(19) United States
(12) Patent Application Publication
(10) Pub. No.: US 2012/0162887 A1
(43) Pub. Date: Jun. 28, 2012

(54) RUGGEDIZED EMF SHIELDEDLCD / PC COMBINATION SYSTEM

(76) Inventor: Guy Purser, Virginia Beach, VA (US)

(21) Appl. No.: 13/050,623

(22) Filed: Mar. 17, 2011

Related U.S. Application Data
(60) Provisional application No. 61/314,772, filed on Mar. 17, 2010.

(51) Int. Cl. H05K 7/00

(52) U.S. Cl. 361/679.08

(57) ABSTRACT

A secure all-in-one LCD or LED-based monitor and computer system includes a chassis enclosing the monitor and multiple computers. Two or more physically and electronically isolated computers are installed within the chassis, each having an independent operating system. The system also includes a power supply, a hardware-based electro-mechanical key/lock preferably with a non-duplicable key for user access. The chassis is constructed of conductive material to mitigate the effects and vulnerabilities between internal computers and outside sources, other computers, or listening devices. The internal computers are separated and isolated by internal walls made of conductive materials to militate against vulnerabilities introduced by multiple computers being hosed inside the same chassis. Rugged components and methods are used in order to withstand extreme shock and vibration as well as low and high operating temperatures.

This Application claims the benefit of U.S. Provisional Patent Application No. 61/314,772 for RUGGEDIZED EMF SHIELDED LCD/PC COMBINATION SYSTEMS, filed on Mar. 17, 2010.

### TECHNICAL FIELD

The embodiments of the present invention relate generally to the field of an all inclusive, all-in-one LCD/computer system, and more particularly, a single computer structure housing an LCD and all working parts for two or more individual computers for purposes of Multi Level Security (MLS) Computing where information between two or more isolated computer networks (or domains) is separated and protected.

### DEFINITIONS

For purposes of clarity, the following definitions will be used in this document.
a. Computer: A computer is a programmable machine designed to sequentially and automatically carry out a sequence of arithmetic or logical operations. Conventionally, it consists of a 1) Computer Processing Unit (CPU) that carries arithmetic and logical operations, 2) memory for temporary storage of data for use by the CPU to read data in order to carry out operations and to write the results of the operations, 3) a sequencing and control element that can change the order of operations and direct communications between the CPU, memory and peripherals, 4) a motherboard and 5) a power source or power supply. The motherboard generally hosts the CPU, memory, and control elements in addition to providing communications between the CPU and control elements to connections for various peripheral devices and communications systems external to the computer. The motherboard may or may not also host a video or graphics adaptor to generate information compatible with a monitor or display device. The computer further includes means for connecting physically, electronically, or otherwise, peripheral devices.
b. Peripherals: Peripheral devices or peripherals allow information to be entered (input) into the computer from external sources and allow the results of the computers operations to be sent out (output). Examples of peripherals include, hard disk drives (HDD) for mass data storage, DVD drives for more permanent data storage and access, Video Adaptors to provide signaling of information to monitors such as Liquid Crystal Displays (LCDs) or Light Emitting Diode (LED) displays, printers, network interfaces to provide a path between other computing devices and remote peripherals, user input devices such as keyboards, mice, and trackballs, to name a few. Peripherals may be connected by direct connection such as cables and the like or via electronic wireless signal. Peripherals may also operate through a network, “cloud” or other means such that the peripheral(s) are not in the same location as the computer, but function in the same manner as peripherals located in physical proximity to the computer.
c. Network; a communications system that allows sharing of resources and information among interconnected computers and peripherals. In many cases, the term network extends past the communications system to include the greater realm of the devices connected to the communications system such as the computers and peripherals. The Internet (World Wide Web) is a network that is generally global and accessible by anyone. There are also networks that are closed to all but authorized users, as well as local networks that are limited to a set number of devices and/or users.
d. Domain: A domain name is an identification label that defines a realm of administrative autonomy, authority, or control in the Internet which is a global network. In the U.S. Government, domains are often used to refer to parts of the government internet that are segmented into individual network enclaves for purposes of information security. Specifically, the U.S. Government has setup three or more specific networks or domains for UNCLASSIFED information, SECRET information, and TOP SECRET Information. Similarly, non-government organizations also setup separate networks or domains or logically divide networks or domains for purposes of information security.
e. TEMPEST. TEMPEST is a U.S. government code word that identifies an unclassified and classified set of standards for limiting electromagnetic radiation emanations from electronic equipment. TEMPEST is both a specification for equipment and a term used to describe the process for preventing emanations and incursions, electronic or otherwise (generally EMI), that can potentially compromise information on a network of computers, individual computers, or other electronic devices.
f. Multilevel Security. The Government refers to computing devices and/or peripherals that can operate at more than one security level or category of security as Multilevel Security (MLS) devices. Specific certification by a government organization such as the National Security Agency is required for all MLS devices prior to connecting to more than one government security network.
g. Electromagnetic Interference (EMI). Electromagnetic interference (or EMI, also called radio frequency interference or RFI) is a disturbance that may affect an electrical circuit due to either electromagnetic induction or electromagnetic radiation. The disturbance may interrupt, obstruct, or otherwise degrade or limit the effective performance of the circuit. The source may be any object, artificial or natural, that carries rapidly changing electrical currents, such as an electrical circuit. The electronic components of a computer or other electronic device accomplish tasks through the switching of electrical current, which generates EMI. During normal operation, therefore, a computer naturally generates EMI. For example, a CPU, described above, accomplishes its tasks through rapid switching of electrical current. Therefore, a CPU is a source of EMI. EMI can be intentionally used for radio jamming, as in some forms of electronic warfare. Additionally, the EMI from a CPU or other parts of a computer may be intercepted and translated, allowing the data being processed by the computer to be read.
h. Wireless or Wirelessly. Wireless describes a means for electrical and electronic components, computers, networks, and the like to communicate data without physical connections such as wire, fiber-optic cable

### BACKGROUND OF THE INVENTION

The U.S. Government protects information sensitive to the country's national security, written or electronic, by categorizing the sensitivity of information and assigning it to a number of categories referred to as “security classifications.” Generally speaking, the classifications are characterized as UNCLASSIFIED (least protected sensitive information) SECRET (more sensitive) to TOP SECRET (most sensitive). Each category of classification is assigned procedural and electronic protection measures. Additionally, within these classifications, there are additional categories directing special handling of the information to further protect the sensitivities associated with origins or content or to limit the number of persons having access to the information. To disseminate and allow for access of information in these security classifications, the U.S. Government supports and in many cases requires individual, separated, and isolated enterprise networks and domains. The networks are protected by a number of technologies with the level of protection increasing dependent upon the sensitivity associated within each classification. In the civilian sector (such as the medical, financial, utility, legal, and other industries) reliance on the concept of protecting information for personal data protection, national security concerns, and client-doctor/attorney relationships use similar methods. This protection can be, and is, also extended to protect confidential business information, trade secrets, and the like. This is most often done by separating public access networks from internal, sensitive networks much the same as the U.S. Government has done. The concept of protecting information based on separation of data is one method the of information security. Further, where the civilian sector is involved in contracts with the U.S. Government, a civilian contractor may be required to utilize the same measures of protection that the U.S. Government would utilize internally. Local and state governments may impose their own restrictions based upon sensitivities as well, or may have standards imposed upon them by the U.S. Government for U.S. Government functions.

Storing, processing, and communicating data inherently has a large number of vulnerabilities, even where the data and/or electronic devices are physically or logically separated. Of these, perhaps the most significant is the vulnerability to human interactions, where the human operator/accessor allows information from one network to enter a second, different network of differing data sensitivities (i.e., unsecured or of a lower clearance classification or vice versa) allowing access to the information by persons not “cleared” or not having access to hold that information. This is referred to as “comprising” data or information, and the information and/or system or device intended to be secure is referred to as “compromised.” In an attempt to limit this vulnerability, government and non-government managers of information place into practice procedural and electronic “access control” measures.

Separation of data is normally achieved through the creation of separate networks implemented through physical separation or virtual separation (where the same physical infrastructure is used but data is logically separated). Protection of the data is achieved through procedural, electronic logic, and physical separation. Controlling access to the data and/or the electronic device(s) is implemented and achieved through procedural (e.g. controlling access to a physical location where a computer or network may be placed), electronic (e.g. password protection on a network to gain access), or in some cases, a combination of both (e.g. issuance and use of a personal SMART Card for users.)

Data can also be introduced between networks and compromised via Electronic and Magnetic Fields (EMF energy) when physical components or wiring are in too close a proximity of one another or when a listening device is introduced near a computer, and/or its User Interfaces (e.g. keyboard, mouse or monitor.) This is normally referred to as Electromagnetic Interference (EMI), bleed over, or cross talk. Two vulnerabilities exist to data when this occurs. First, there is a possibility of one computer “jamming” the next computer if the EMI generated by the first is “loud” enough for its radiated energy to interrupt the correct logical operations of the second computer. Secondly, if two computers are in close enough proximity to one another, there is a potential to “listen” to the first computer from the second computer. To mitigate this vulnerability, procedural and electronic measures are taken referred to as TEMPEST controls.

When institutions implement and rely on multiple networks for security purposes, multiple computers are employed connected to each, but only one, of the separated networks. A user must have a computer connected to each of the separated networks in order to access the information residing on each of the networks. When multiple networks and computers are employed, the working space becomes dominated by the requirement to provide multiple computers to every worker that requires access to the networks. While this methodology separates the information, many new vulnerabilities to the security of the data are created and new problems are introduced to the workspace. For instance, new vulnerabilities are introduced with respect to EMI and access control. Due to the vulnerabilities to data presented by EMI, computers must be separated by a distance (the U.S. Government specifies 30-36 inches of separation between individual commodity computers residing on each of its network classifications for this reason.) This requirement drives the overall size of a workspace and workspace utilization. Each desk space must support at least 72″ of floor space if three computers are required.

Additionally, the spacing of other workspaces is driven by the placement of each computer at the first workspace. And multiple keyboards/mouse and monitors are required for each computer residing on each network. Each keyboard/mouse and monitor require either individual wiring or require wiring to a Keyboard, Video, Mouse (KVM) switch that is implemented to combine operations of a single set of Keyboard, Mouse, and monitor to multiple computers. But even with an exposed KVM switch, the workspace is still cluttered with multiple wires and these exposed connections are not only a hindrance to the workspace but also introduces a human error potential where wires between networks can be confused and mis-wired leading to the compromise of data and information. Where multiple levels of security are introduced into a single workspace, the issue of controlling access to all of the security classifications of computers becomes another issue. Where users in the same workspace do not have the same “clearance” or permissions to access all of the information of the classifications, access control features and procedures must be implemented. Computers of the highest level security classifications must be protected from those not holding the correct clearance. The ability to move information from one network to another must also be controlled.

In addition, the more physical components that are required in a workspace and under security-controlled conditions, the more complexity arises in the logistical support to the computer center. The greater the individual units (i.e., individual components) the greater the requirement for accounting, repair, maintenance, etc. related to administering a computer network or center.

With the continued reduction in size of computer components, computer manufacturers have attempted to clean up the workspace issue of wire and space by housing a LCD monitor and computer into a single chassis with an associated keyboard and mouse as opposed to a monitor, desktop computer and computer and mouse. This is normally referred to as an “all-in-one computer/monitor system.” The resultant computer product eliminates the separate computer chassis and reduces the overall computer footprint (computer, monitor, keyboard, and mouse) to a single chassis with the approximate size a an LCD monitor with the depth or thickness of the monitor being only a slightly greater in depth in order to house the motherboard, CPU, memory and peripherals behind the LCD panel of the monitor. Some manufacturers of computers have implemented TEMPEST features into their computers to overcome the issue of EMI allowing them to be placed closer to one another. While both of these measures, smaller integrated computers and TEMPEST protections, provide some solution, neither eliminates the requirements for multiple computer workstations, the complete separation required between the computers, or the confusing wiring running among the computers.

Further, prior designs of all-in-one computer/monitor systems have been made primarily for commercial use and do not have access control features required by the U.S. Department of Defense or the National Institute for Standards and Technology to mitigate the vulnerabilities associated with access control. Such access control features may include a physical key to access the computer and a Smartcard for user access, authentication, and identification.

In addition, prior art systems do not incorporate the features required to operate computers, in close proximity or in a single chassis, and also provide positive access control to the computers in adequate fashion to mitigate vulnerabilities to both areas of potential compromise of information.

Last, commercially available systems do not meet or withstand severe shock and vibration requirements or high operating temperature capabilities that are typical of tactical and military applications. Prior art systems typically rely on conventional power supplies which render the systems unfit for mobile applications.

What is needed, therefore, is a computer system that is designed to meet or exceed all the above requirements and overcome the shortcomings of prior art all-in-one monitor/computer systems.

### SUMMARY OF THE PRESENT INVENTION

Embodiments of the present invention are directed toward a hardware based, Multi-Level Security (MLS), all-in-one monitor/computer system with access control features, two or more computers housed internally to a single chassis with a Keyboard, Mouse, and Video switching systems to allow the operator to switch to the computer of choice and need and where all computers are fully functional and available to the user simultaneously. The system includes a housing or chassis for enclosing all components of two or more computer devices, design considerations to overcome information compromise vulnerabilities as a result of EMI, a single LCD or LED monitor, a secure KVM switch to switch Keyboard, Mouse, and Monitor functions between the two or more computers devices, and access control features. The housing is typically the size of a standard 20″˜24″ (or larger or smaller) Liquid Crystal Display (LCD) or Light Emitting Diode monitor (or future technology display systems involving lasers or other technologies). A LED monitor or LCD monitor is disposed within the same housing as the multiple instantiations of computers. The power supply or supplies may be internal or external to the chassis. The system also contains an internal, integrated Keyboard, Video, and Mouse (KVM) switch to switch the independent computers, one at a time, to the Keyboard, Mouse, and Video/Monitor. The system may also contain some common computer peripherals (e.g. DVD optical drives, Hard disk drives, CompactFlash memory, smart card readers) dependent upon the exact user requirements for a MLS computer. In one embodiment, the housing is constructed of a conductive material or treated with a conductive stratum to reduce or eliminate EMI emissions between internal computer components and between multiple instantiations of all-in-one computers/monitors or other computers or listening devices. Included are access control features that restrict access to the system to authorized users or maintenance personnel. Last, the computer may or may not be constructed using fasteners and power supply technology that allows the computer to be used in the rugged specifications of military tactical employment.

The computer components may be mounted to the housing/chassis using torque locking screws, rubber studs or other technologies to minimize damage from shock and vibration. Note that the ruggedized configuration is not necessary for this computer to operate in an office environment and therefore is not necessarily required in all instantiations.

The computer will utilize a technique such as an electro-mechanical key lock to start the computer to ensure only those authorized to hold a key can access/start the computer. Either high-torque hex screws with security drive heads, locks, or other access control techniques will be used to prevent easy access to the inside components of the system to anyone except for authorized personnel. Last, all peripheral connections to networks and other peripheral devices not integrated inside of the chassis will be covered and the cover locked to ensure only authorized personnel can correctly configure and connect peripheral devices to the system.

The embodiments of the present invention provide a secure, MLS all-in-one monitor/computer system characterized by enhanced data security from within that prevents inside unauthorized user access as well as outside unauthorized user access via the Internet or other computer network. Other characteristics of the embodiments described herein include an ability to be used in critical operating environments for secured and unsecured networks that need to be viewed without delays. The system is rugged and able to withstand the harsh environments of the battlefield, whether it is in a vehicle-mount or wall-mount configuration.

Other advantages of the invention embodiments include: a reduced footprint; reduced power consumption; reduced heat output; reduced EMF emissions; reduced maintenance and acquisition costs; and reduced life cycle system costs.

These and other features as well as advantages, which characterize the various embodiments of present invention, will be apparent from a reading of the following detailed description, drawings and the associated claims.

### DESCRIPTION OF THE DRAWINGS

FIG. 1 illustrates a system block diagram of an embodiment of the present invention with two internal computers.

FIG. 2 is a front view of an embodiment of the present invention.

FIG. 3 is a rear view of an embodiment of the present invention.

### DETAILED DESCRIPTION OF PREFERRED EMBODIMENTS

Referring now to the drawings, in which like numerals represent like elements, exemplary embodiments of the present invention are described herein.

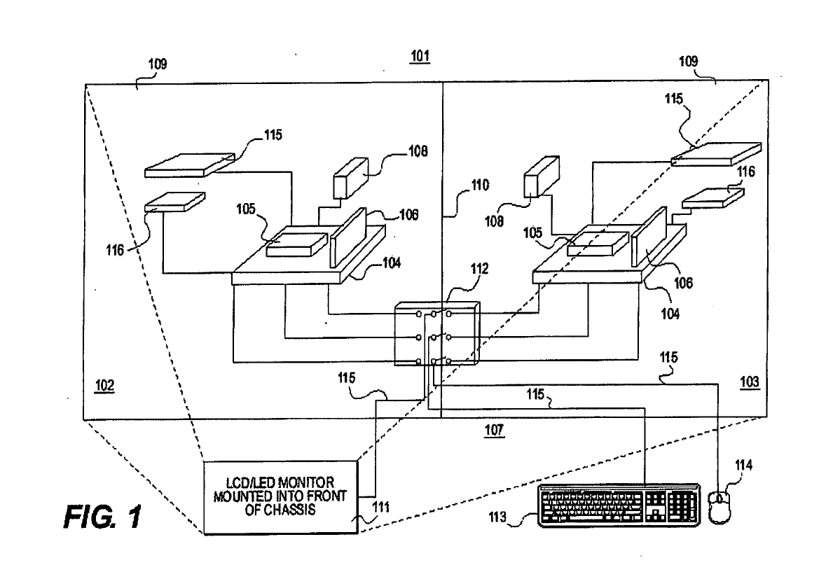

FIG. 1 illustrates an exemplary embodiment of the system 101 according to the present invention. The system 101 as shown comprises a first computer 102 and a second computer 103, consisting each of a motherboard 104, a CPU 105, and memory 106. Each motherboard 104 is mounted internal to the chassis 107. A combined set of a motherboard 104, CPU 105, and memory 106 together are considered a computer for the purposes of this invention. The chassis 107 further comprises one or more compartments 109, each one or more computers 102 and 103 residing within its own compartment 109. The manner of connection between the components comprising a single “computer” as well as the means of communication are well known in the art, and it will be understood by those skilled in the art that the term “computer” is read in its broadest sense, to include any combination of hardware and software that provides computing ability and that may be utilized in the manner of this invention to achieve the purposes of this invention. To that end, the construction of a “CPU,” “motherboard,” “memory,” “display,” “peripherals,” and/or any other computer component that can still function as a “computer” will fall within the scope of this invention. In addition, any and all means of connecting and communicating between such computer components for the operation of the computer will fall within the scope of this invention. In one embodiment, one or more of the computer 102 and 103 components may be physically connected by wire, fiber optic cable and the like, and in another embodiment the components may be connected wirelessly. The present to invention, therefore, should not be read to be limited by the manner of construction and operation of the computer itself. Other well-known and well-understood components such as a power supply 108 will be understood as commonplace in a computer system. In a preferred embodiment, each one or more computers 102 and 103 has its own powers supply 108, and the power supply 108 is also isolated such that it is shielded from outside EMI and also does not emit outside the compartment 109 in which the computer 102 and 103 that it provides power to is located.

It will be well understood by those skilled in the art that the memory 106 may be located on and directly connected to the motherboard 104, external to but communicatively connected to the motherboard 104, or a combination thereof. It will also be well understood that the memory may comprise mechanical, solid state, or other means known in the art.

In the mounting and chassis 107 construction, each computer 102 and 103 is isolated from one another using the chassis 107 wall material or stratum material and interior chassis walls 110 or stratum material to isolate each computer 102 and 103 compartment 109 from the other in order to 1) isolate the whole of the enclosure from other computers or listening devices from the effects and vulnerabilities of EMI and 2) isolate the internal computers 102 and 103 from one another against the effects and vulnerabilities of EMI. The LED/LCD monitor 111 is enclosed in the front of the chassis.

The power supply 108 devices may or may not be enclosed in the chassis 107. Additionally, dependent upon a user's requirement for system interfaces, common peripheral devices as described earlier may be enclosed in the chassis with the computers. A KVM switch 112 will be hosted internal to the chassis 107. As shown, the keyboard 113 and mouse 114 are external and are considered to be peripheral devices not germane to the invention but as common user interface devices shown here for explanation of how the KVM switch 112 electronically switches operation of the computers 102 and 103 between the keyboard 113, LCD/LED monitor 111, and mouse 114. The keyboard 113, LCD/LED monitor 111, and mouse 114 are electrically connected 115 to the KVM switch 112 as shown. In the embodiment shown, the KVM switch 112 functions as a triple-pole single-throw switch that is used to select connecting the keyboard 113, LCD/LED monitor 111, and the mouse 114 as a group to either the first computer 102 or the second computer 103 (as shown). It will be understood that the triple-pole single-throw KVM switch 112 as shown is utilized in a system 101 comprising two computers 102 and 103; the addition of computers and/or peripherals may necessitate utilizing switches with corresponding multiple poles and multiple throws, and/or combinations of switches. In one embodiment, the KVM switch 112 allows a user to select between two or more computers that have different classifications but may be operated from a single location, thus isolating use of classified computer systems and/or networks from each other and from non-classified computer systems and/or networks. In yet another embodiment, the KVM switch 112 further includes data security functions and means.

Further desired peripheral devices may include a DVD optical drive 115, storage device 116, or other common peripheral devices.

The chassis 107 will preferentially be constructed from lightweight, high strength aluminum metal or other lightweight material, preferably conforming to U.S. military standards for rugged computing devices and offering good conductive properties to reduce the effects and vulnerabilities of EMI between computing domains and between other computers in proximity or will have a stratum layer of highly conductive material. Power supplies 108 are nominally divided into two functions; one to convert external supplied power to the basic 12 VDC power requirements of a generic computer and a second regulatory power function to provide stable power to the computer and step the power to the lower 5 VDC and 3.3 VDC required for the computer. The power supply 108 may be, in total, external to the chassis or separated according to functions and placed external and internal to the chassis. The chassis 107 shall conform to VESA (Video Electronics Standards Association) for mounting in order to take advantage of various standard mounting options for vehicles, monitor stands, and monitor brackets.

A hardware-based electromechanical key/lock (not shown) is preferentially installed on the chassis for each enclosed computer and wired to prevent the power supply from passing power to the computer when key is in the off position to prevent unauthorized attempts to power the system on except to those authorized users who have been issued a key. There are various schemes in which the electromechanical key lock can be wired to accomplish this; the method is not relevant to the invention; the fact that the power resource to the computer is enabled through the key lock is germane. Additionally, a separate push-button on switch (not shown) is installed for each computer 102 and 103 enclosed in the chassis. The on/off/reset switch only operates when a key is inserted in the electromechanical key/lock and turned clockwise to power on the power supply. In a preferred embodiment, the rear cover of the chassis 107 is attached by fasteners and includes a locking device, key actuated, to ensure only authorized holders of the key can gain entrance to the internal components of the chassis. Further, in a preferred embodiment, there is provided a key locking cover to the panel where computer peripherals such as keyboard 113, mouse 114, network connections and other peripherals are located to prevent unauthorized access to those peripherals in order to further protect the integrity of information between networks. If the requirements for the computer 102 and 103 requires a Hard Disk Drive, Solid State Disk Drive, or CompactFlash memory, removable carriers for those devices may further be included within the system 101, wherein the Hard Disk Drive, Solid State Disk Drive, CompactFlash memory or other removable memory is operated with a key lock thus allowing operators to remove sensitive data from the computer and secure the data on the mass memory peripherals in a secure location of their choice. Additionally, a secondary monitor may be attached to each computer 102 or 103 using a video output connection (not shown) from each computer 102 or 103 interfaced under the locking peripheral cover.

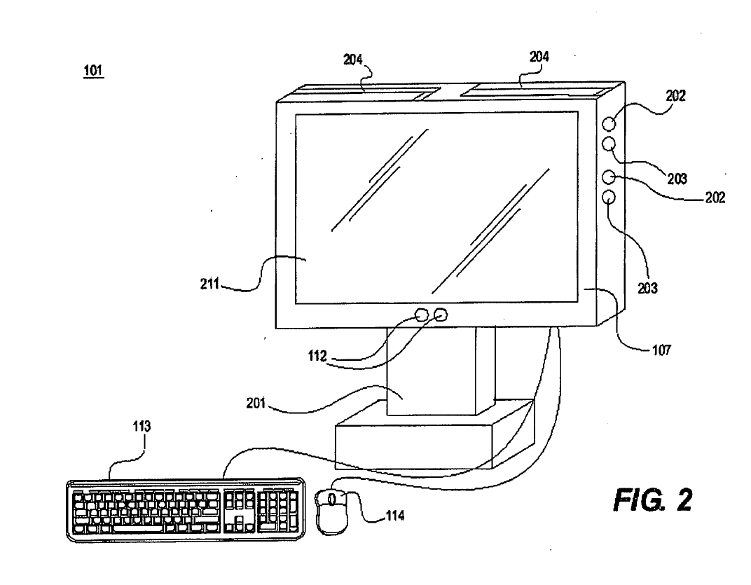

Referring now to FIG. 2, a front view of the system 101 is shown according to embodiments of the invention. The monitor chassis 107 is made from, for instance, aluminum. The monitor 211 itself can be, for instance, an LCD or LED type having a glass covering and mounted internal to the chassis. In the two computer illustration, two KVM buttons 112 are provided on the chassis 107 to allow the user to switch the attached keyboard 113 and mouse 114 peripherals as well as the monitor 211 between the two computers. Removable Hard Disk Drives 204 are illustrated and can be incorporated according to user requirements. In a preferred embodiment, electromechanical key locks 202 to actuate power to each computer, one for each computer hosted within the chassis, are mounted to the chassis wall as are the ON/OFF/RESET switches 203 for each computer.

A monitor stand 201 is included in the illustration and it will conform to the VESA standard attachment points on the rear of the chassis 107. Additionally, the chassis's 107 top and bottom ends as well as its sides can include vents (not shown) for dispersing any internally generated heat during use of the system 101.

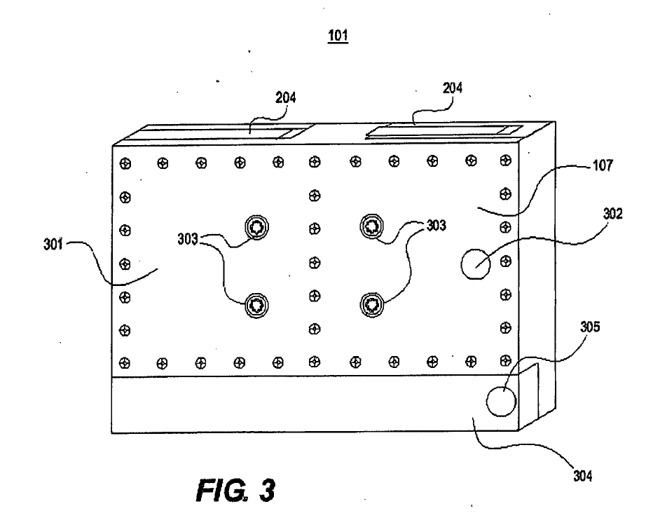

Referring now to FIG. 3, a rear view of the system 101 according to embodiments of the invention is shown. In this view the back of chassis 107 is also made of a highly conductive metal or covered with a stratum of conductive material. The rear cover 301 is fastened to the chassis 107 and has a locking key access 302 that allows only authorized access to the internal components of the chassis 107. Also shown are the four VESA standard mounting locations 303 for a monitor stand (FIG. 2, 201). The chassis 107 may further comprise a peripheral panel 304 with locking means 305 that prevents any unauthorized access to the peripheral connections. When closed, two or more small diameter half hole openings (not shown) are placed in the leading edge of the bottom of the panel to allow the peripheral connections to pass up and into the peripheral connections covered by the panel peripheral panel 304 when closed and locked. The peripheral I/O ports may include, but are not limited to, USB ports, Ethernet ports, audio jacks, video jacks, microphone jacks, serial ports, parallel ports, external SATA ports and other peripheral I/O provided by any of a number of motherboard. It will be understood by those skilled in the art that the construction of computers and peripheral devices is subject to constant redesigns and upgrades as the design of equipment progresses; the peripherals and manners of connection listed herein as examples should not be read to be limiting as the peripheral I/O port types and configurations will change as the art progresses.

The entire internal surface of the cover 301 is highly conductive in order reduce EMI transmission or reception. This is preferentially accomplished by either utilizing in the cover 301 construction the type of material used to build the chassis 107, or by a stratum applied to the internal chassis 107 components.

In one embodiment, a secured “Classified” hard drive is defined by its own secure operating system and a removable hard drive 204 with a lock key (not shown). This drive 204 stores data which, by definition, is a domain level having restricted access. When the secured hard drive authorized user completes his or her assignment, they can then perform normal system shutdown and remove the hard drive without affecting the operation of the unsecured internal hard drive.

The security features of the system may include access control, identification, authentication, and switching mechanisms that are entirely hardware based. In one embodiment, access control may require an access key for the electromechanical on/off key lock to turn on the system by inserting the key into the key lock. Authorized users in possession of a removable hard drive lock can unlock and remove the removable hard drive from the system and store it in a safe place.

While the various embodiments of this invention have been described in detail with particular reference to exemplary embodiments, those skilled in the art will understand that variations and modifications can be effected within the scope of the invention as defined in the appended claims. Accordingly, the scope of the various embodiments of the present invention should not be limited to the above discussed embodiments, and should only be defined by the following claims and all applicable equivalents.

1. A Multi Level Security all-in-one monitor/computer system comprising:
a lightweight metal chassis of electromagnetic conductivity or with a stratum of material that is electromagnetic conductive for minimizing EMF emissions, the chassis containing:
at minimum, two computers comprised of at minimum: a motherboard, a CPU, and memory
interior dividing walls of conductive materials to isolate the EMI effects of one internal computer from the second (or third, fourth dependent upon the security classifications required)
exterior chassis walls of conductive materials to isolate the EMI effects of internal computers to external computers and external to internal computers.
A power supply internal or external to the chassis a single monitor mounted internal to the chassis
An integral KVM capable of switching the internal monitor and a keyboard and mouse
a plurality of I/O ports for each internal computer for connecting to networks and for connecting with peripheral devices dependent on user requirements; and
a hardware-based electromechanical lock/key for preventing unauthorized access to the system electrically coupled between the power supply and the mechanical on/off switch.

2. The all-in-one monitor/computer system of claim 1 further comprising a mounting bracket that can be wall-mounted or vehicle-mounted or adapted to sit on a table top.

3. The all-in-one monitor/computer system of claim 1 wherein the chassis further contains: a compact motherboard; CPU; memory; two Ethernet ports; USB ports; a second video monitor port; a MIC/Audio port; an external SATA port; a serial port and other common motherboard peripheral ports as computer peripheral interfaces develop and grow in popularity.

4. The all-in-one monitor/computer system of claim 1 wherein the hard drives can be permanently installed or mounted in removable hard drive assemblies.

5. The all-in-one monitor/computer system of claim 1 wherein all components within the chassis are mounted using torque-screws and rubber-mounted subcomponents to reduce shock and vibration when operating in less than ideal environments characterized by extreme shock and vibration.

6. The all-in-one monitor/computer system of claim 1 wherein an LED colored light is mounted on the front next to or within the on/off/reset switch indicating that the system is active and powered on.

7. The all-in-one monitor/computer system of claim 1 wherein the monitor is a liquid crystal display (LCD) monitor.

8. The all-in-one monitor/computer system of claim 1 wherein the monitor is a light emitting diode (LED) monitor.
